(19) United States
(12) Patent Application Publication
(10) Pub. No.: US 2015/0364591 A1
(43) Pub. Date: Dec. 17, 2015

(54) HEMT DEVICE AND FABRICATION METHOD

(71) Applicant: Huawei Technologies Co., Ltd., Shenzhen (CN)

(72) Inventor: Wei LU, Shanghai (CN)

(21) Appl. No.: 14/734,829

(22) Filed: Jun. 9, 2015

(30) Foreign Application Priority Data
Jun. 11, 2014 (CN) 201410257470.6

(51) Int. Cl. H01L 29/778; H01L 23/373; H01L 23/367; H01L 29/45; H01L 29/66

(52) U.S. Cl. CPC H01L 29/7788; H01L 29/45; H01L 29/66431; H01L 23/367; H01L 23/373

(57) ABSTRACT

A HEMT device, including: a substrate, a nucleating layer, a buffer layer, a channel layer, and a barrier layer, and a source, a gate, and a drain that are formed on the barrier layer, the substrate is provided with a device surface disposed facing the nucleating layer and a substrate back surface away from the device surface, a source back hole and a channel back hole are opened on the substrate back surface, the source back hole penetrates through the substrate, the nucleating layer, the buffer layer, the channel layer, and the barrier layer and extends to the source, the channel back hole penetrates through at least one part of the substrate, the HEMT device is further provided with a thermally and electrically conductive layer, and the thermally and electrically conductive layer is filled in the source back hole and the channel back hole and covers the substrate back surface.

### CROSS-REFERENCE TO RELATED APPLICATIONS

This application claims priority to Chinese Patent Application No. 201410257470.6, filed on Jun. 11, 2014, which is hereby incorporated by reference in its entirety.

### TECHNICAL FIELD

The present invention relates to the field of semiconductor technologies, and in particular, to a HEMT device and a fabrication method.

### BACKGROUND

A HEMT (High Electron Mobility Transistor, high electron mobility transistor) device is a semiconductor electronic device, and a wide band gap semiconductor nitride heterojunction (AlGaN/GaN) on the HEMT device is considered by the industry as an optimum material for fabricating a high power radio frequency device and a high pressure resistant switch device due to advantages of a high breakdown electric field, a high concentration of channel electrons (2DEG, a two dimensional electron gas of an AlGaN/GaN interface), a high electron mobility, and high temperature stability. As a third generation semiconductor, a theoretical output power density of an AlGaN/GaN HEMT device can reach 10 W/mm to 20 W/mm, and is almost one order of magnitude higher than output power densities of a GaAs HEMT device and a Si LDMOS (laterally diffused metal oxide semiconductor) device. With such a high output power density, besides implementation of high output power, in the case of same output power, compared with other semiconductor devices, the AlGaN/GaN HEMT device can effectively reduce a device size, and improve device impedance (making matching easier), so as to obtain larger bandwidth. In addition, a high breakdown voltage also enables the AlGaN/GaN HEMT device to be simplified during wireless application, and even omit a power supply conversion circuit, thereby improving voltage conversion efficiency. However, while a high power density brings beneficial effects to a device, the high power density also has higher requirements on heat dissipation of the device, because when the device runs, increasing of temperature seriously deteriorates performance, an output power capability, and reliability of the device.

In the prior art, an AlGaN/GaN HEMT material is generally obtained through epitaxial growth on a Sapphire (sapphire, Al₂O₃) substrate, a Si (silicon) substrate, or a SiC (silicon carbide) substrate. A limited heat-conducting property of a substrate limits maximum output power and reliability of a HEMT device to a large extent.

At present, a method for improving a heat dissipation capability of a device is generally: horizontally improving a distance between adjacent gates of a HEMT device; vertically using SiC as an epitaxial substrate, and using a substrate thinning process (thinned to 50 μm to 100 μm) to lower thermal resistance of the device, so that when the device runs, heat generated in a channel (at 2DEG) is quickly conducted to a metal tube with better heat dissipation performance by using a substrate having low thermal resistance.

In order to improve output power of a device, a multi-finger (multi-finger) gate structure is generally used. An electrical connection is generally performed on separated source metal by means of an air bridge (or a medium bridge) or a source back hole (or both a medium bridge and a source back hole). Compared with an air bridge (or a medium bridge) process, a source back hole is formed by using an etched and thinned SiC substrate, and then, source metal is led to an electroplating metal ground of a substrate back surface through the source back hole by electroplating (generally, <10 μm Au). However, a gap in a back hole easily forms an air gap when the HEMT device is soldered to a metal tube, affecting a heat conduction effect.

Another method for improving heat dissipation of a device is: after epitaxial growth of an AlGaN/GaN HEMT is complete on the SiC substrate, thinning a SiC substrate and etching a back hole immediately, depositing thick high heat conducting material diamond (diamond) on a back surface by using a CVD (Chemical Vapor Deposition, chemical vapor deposition) method to fill a SiC back hole, and then fabricating a HEMT device conventionally. The SiC substrate is partially replaced with the high heat conducting material diamond (1000 W/mK) to improve a heat dissipation capability of the device.

Because thick diamond deposition generally needs to be performed by using the CVD method having a quicker growth speed, a high growth temperature is required, and the temperature easily causes disadvantages of affecting a gate feature, passivation, affecting a breakdown voltage, and the like, and is not compatible with a front-end process of a universal HEMT device, the process must be completed before the front-end process related to gate processing. Therefore, before diamond grows, in order to protect a surface of the AlGaN/GaN HEMT material, SiNx needs to be deposited temporarily for AlGaN/GaN surface protection, and is removed after diamond deposition is complete. In the step, a density of electron traps on the surface of the AlGaN/GaN HEMT material may be increased, and current collapse of a device increases (a drain current in a case in which a device runs in an RF situation is lower than a DC drain current in an ideal situation); in addition, because etching of a substrate and diamond filling of a back hole of the substrate in the process are completed before a source metal process, an extra complex process needs to be performed to implement an electrical connection between source metal and a metal ground of a substrate back surface.

### SUMMARY

A HEMT device and a fabrication method are provided, which can improve a heat conducting capability of the HEMT device, and are compatible with a processing process of a back hole of an existing HEMT device.

According to a first aspect, a HEMT device is provided, including: a substrate, a nucleating layer, a buffer layer, a channel layer, and a barrier layer that are disposed in a laminating manner, and a source, a gate, and a drain that are formed on the barrier layer, where the drain is disposed between the source and the gate, and the substrate is provided with a device surface disposed facing the nucleating layer and a substrate back surface away from the device surface, a source back hole and a channel back hole are opened on the substrate back surface, the source back hole penetrates through the substrate, the nucleating layer, the buffer layer, the channel layer, and the barrier layer and extends to the source, the channel back hole penetrates through at least one part of the substrate, the HEMT device is further provided with a thermally and electrically conductive layer, and the thermally and electrically conductive layer is filled in the source back hole and the channel back hole and covers the substrate back surface.

In a first possible implementation manner of the first aspect, the thermally and electrically conductive layer is made of high thermal conductivity metal.

With reference to the first possible implementation manner of the first aspect, with reference to a second possible implementation manner of the first aspect, the thermally and electrically conductive layer is made of copper.

In a third possible implementation manner, the channel back hole penetrates through the substrate.

In a fourth possible implementation manner, the channel back hole penetrates through the substrate, and the channel back hole extends into the nucleating layer.

In a fifth possible implementation manner, the channel back hole penetrates through the substrate and the nucleating layer.

In a sixth possible implementation manner, the channel back hole penetrates through the substrate and the nucleating layer, and the channel back hole extends into the buffer layer.

In a seventh possible implementation manner, the channel back hole penetrates through the substrate, the nucleating layer, and the buffer layer.

With reference to the third to the seventh possible implementation manners of the first aspect, in an eighth possible implementation manner, the HEMT device is further provided with a high heat conducting layer, the high heat conducting layer is laid in the channel back hole, and the high heat conducting layer is disposed between the substrate back surface and the thermally and electrically conductive layer.

With reference to the eighth possible implementation manner of the first aspect, in a ninth possible implementation manner, the high heat conducting layer is made of a diamond-like carbon material.

According to a second aspect, a HEMT device fabrication method of the HEMT device according to the first aspect and the first to the ninth possible implementation manners includes:

disposing a substrate, a nucleating layer, a buffer layer, a channel layer, and a barrier layer, and disposing a source, a gate, and a drain on the barrier layer, so that the drain is disposed between the source and the gate;

forming a source back hole and a channel back hole on a substrate back surface, where the channel back hole penetrates through at least one part of the substrate;

making the source back hole penetrate through the substrate, the nucleating layer, the buffer layer, the channel layer, and the barrier layer and extend to the source; and

disposing a thermally and electrically conductive layer on the substrate back surface, where the thermally and electrically conductive layer is filled in the source back hole and the channel back hole and covers the substrate back surface.

In a first possible implementation manner of the second aspect, the forming a source back hole and a channel back hole on a substrate back surface includes: forming the source back hole and the channel back hole by etching.

In a second possible implementation manner of the second aspect, after the forming a source back hole and a channel back hole on a substrate back surface, the HEMT device fabrication method further includes:

etching the channel back hole, to extend the channel back hole into the HEMT device.

With reference to the second possible implementation manner of the second aspect, in a third possible implementation manner of the second aspect, the HEMT device is further provided with the nucleating layer, and when the channel back hole is etched, the etching the channel back hole includes: extending the channel back hole into the nucleating layer.

With reference to the second possible implementation manner of the second aspect, in a fourth possible implementation manner of the second aspect, the etching the channel back hole includes: etching the channel back hole so as to penetrate through the nucleating layer.

With reference to the second possible implementation manner of the second aspect, in a fifth possible implementation manner of the second aspect, the etching the channel back hole includes: etching the channel back hole, to extend the channel back hole into the buffer layer.

With reference to the second possible implementation manner of the second aspect, in a sixth possible implementation manner of the second aspect, the etching the channel back hole includes: etching the channel back hole so as to penetrate through the nucleating layer and the buffer layer.

In a seventh possible implementation manner of the second aspect, before the disposing a thermally and electrically conductive layer on the substrate back surface, the HEMT device fabrication method further includes: disposing a high heat conducting layer on the substrate back surface and in the channel back hole.

In an eighth possible implementation manner of the second aspect, after the disposing a thermally and electrically conductive layer on the substrate back surface, the HEMT device fabrication method further includes: grinding and polishing the substrate back surface.

With reference to the eighth possible implementation manner of the second aspect, in a ninth possible implementation manner of the second aspect, when the thermally and electrically conductive layer is disposed on the substrate back surface, a thickness of the thermally and electrically conductive layer is greater than a depth of each of the source back hole and the channel back hole.

According to the HEMT device and the fabrication method of the HEMT device that are provided according to various implementation manners, a channel back hole is formed, a high heat conducting layer is formed in the channel back hole through deposition, and a thermally and electrically conductive layer is electroplated on a substrate back surface, so that a heat conducting capability is improved, and a source is connected to a metal ground of the substrate back surface through a source back hole. The high heat conducting layer and the thermally and electrically conductive layer of the HEMT device of the present invention are formed through low-temperature or room-temperature deposition after the source back hole and the channel back hole are etched. The fabrication method is compatible with a process of a conventional source back hole, which does not affect performance of the HEMT device.

### BRIEF DESCRIPTION OF DRAWINGS

To describe the technical solutions in the embodiments of the present invention more clearly, the following briefly introduces the accompanying drawings required for describing the embodiments. Apparently, the accompanying drawings in the following description show merely some embodiments of the present invention, and a person of ordinary skill in the art may still derive other drawings from these accompanying drawings without creative efforts.

FIG. 1 is a top view of a HEMT device according to a first exemplary implementation manner of the present invention;

FIG. 2 is a schematic partial section view of the HEMT device according to the first exemplary implementation manner of the present invention;

FIG. 3 to FIG. 6 are schematic partial section views of the HEMT device shown in FIG. 1 at various fabrication stages;

FIG. 7 is a schematic flowchart of a HEMT device fabrication method of the HEMT device shown in FIG. 2;

FIG. 8 to FIG. 11 are schematic structural diagrams of a HEMT device according to a second exemplary implementation manner of the present invention;

FIG. 12 is a schematic flowchart of a HEMT device fabrication method of the HEMT device shown in FIG. 8 to FIG. 11;

FIG. 13 is a schematic structural diagram of a HEMT device according to a third exemplary implementation manner of the present invention; and

FIG. 14 is a schematic flowchart of a HEMT device fabrication method of the HEMT device shown in FIG. 13.

### DESCRIPTION OF EMBODIMENTS

The following clearly describes the technical solutions in the embodiments of the present invention with reference to the accompanying drawings in the embodiments of the present invention. Apparently, the described embodiments are merely a part rather than all of the embodiments of the present invention. All other embodiments obtained by a person of ordinary skill in the art based on the embodiments of the present invention without creative efforts shall fall within the protection scope of the present invention.

In the following detailed description, when it is described that an element such as a layer, an area, or a substrate is “on” another element, the element may be directly on the another element, or an element may also be disposed between the two. In addition, relative terms such as “in”, “out of”, “on”, “under”, “among”, and “outside” and similar terms thereof in the document can be used for describing a relative relationship between one layer and another area.

In addition, the accompanying drawings provided in the present invention are exemplary drawings. It may be understood that the elements, layers, and areas described in the present invention can have relative sizes different from sizes shown in the accompanying drawings of the specification. Shapes in the drawings can be correspondingly modified due to fabrication technologies and/or tolerances. The embodiments of the present invention shall not be explained as being limited to specific shapes of various areas shown in the document, and shall include, for example, a deviation of a shape caused by fabrication. Therefore, the accompanying drawings are essentially exemplary, and are not intended to limit the scope of the present invention.

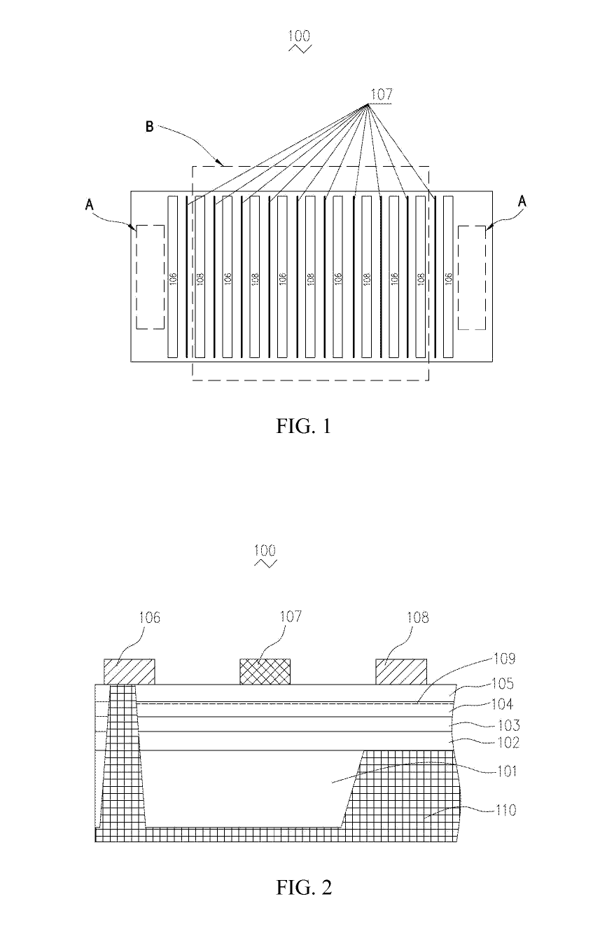

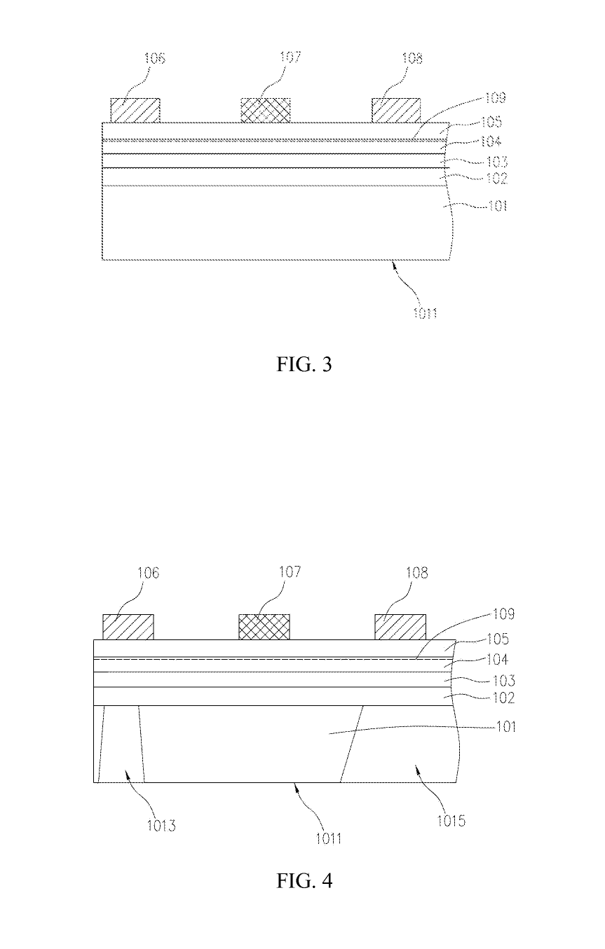

Referring to FIG. 1 and FIG. 2, a first exemplary implementation manner of the present invention provides a HEMT (High Electron Mobility Transistor, high electron mobility transistor) device 100, including a substrate 101, a nucleating layer 102, a buffer layer 103, a channel layer 104 and a barrier layer 105, and a source 106, a gate 107, and a drain 108 that are formed on the barrier layer 105. The nucleating layer 102, the buffer layer 103, the channel layer 104, and the barrier layer 105 are formed on the substrate 101 and are successively disposed in a laminating manner.

In this embodiment, the substrate 101 may be a Si (silicon) substrate, a SiC (silicon carbide) substrate, or an Al₂O₃ (sapphire, Sapphire) substrate.

The HEMT device 100 in the present invention may use Metal-organic Chemical Vapor Deposition (metal-organic chemical vapor deposition, MOCVD) or MBE (molecular beam epitaxy, Molecular Beam Epitaxy) as a growing tool, and the nucleating layer 102 and the buffer layer 103 are formed on the substrate 101 by growing.

In this embodiment, the nucleating layer 102 is made of GaN (gallium nitride), AlN (aluminum nitride), AlGaN (gallium aluminum nitride), or a combined layer of GaN, AlN, and AlGaN. Both the buffer layer 103 and the channel layer 104 are made of GaN or AlGaN. The barrier layer 105 is made of AlGaN (Al content of the barrier layer 105 is different from Al content of each of the buffer layer 103 and the channel layer 104), and is used for cooperating with the channel layer 104 and generating a two dimensional electron gas (2DEG) 109 under the effect of polarization in a connection area of the channel layer 104 and the barrier layer 105, so as to conduct a current. The source 106 and the drain 108 are used for enabling, under the electric field effect, the two dimensional electron gas 109 to flow in the channel layer 104 between the source 106 and the gate 107, and conduction between the source 106 and the drain 108 occurs in the two dimensional electron gas 109 in the channel layer 104. The drain 108 is disposed between the source 106 and the gate 107, and is used for allowing or hindering passing of the two dimensional electron gas 109. The source 106, the drain 108, and the gate 107 may be made of any suitable metal or other materials.

It may be understood that the HEMT device 100 may further be provided with a spacer layer (not shown in the figure), the spacer layer is disposed between the channel layer 104 and the barrier layer 105, and the spacer layer may be made of AlN having a large band gap (band gap), to enhance the polarization effect, and improve a concentration of the two dimensional electron gas 109. It may be understood that layers in this embodiment may be set or omitted as required.

In this embodiment, the substrate 101 is provided with a device surface (not shown in the figure) disposed facing the nucleating layer 102 and a substrate back surface 1011 away from the device surface. In other words, the device surface and the substrate back surface 1011 are respectively a top surface and a bottom surface of the substrate 101. The HEMT device 100 has a source back hole 1013 and a channel back hole 1015 opened on the substrate back surface 1011. In this embodiment, the source back hole 1013 penetrates through the substrate 101, the nucleating layer 102, the buffer layer 103, the channel layer 104, and the barrier layer 105 and extends to the source 106. The channel back hole 1015 penetrates through the substrate 101 and extends to the nucleating layer 102.

The source back hole 1013 is provided, so that the HEMT device 100 is connected to a metal ground of the substrate back surface 1011 by using an electrically conductive medium. The channel back hole 1015 is used for improving a heat conducting capability of the HEMT device 100.

In this embodiment, the HEMT device 100 is further provided with a thermally and electrically conductive layer 110, the thermally and electrically conductive layer 110 is formed and covers the substrate back surface 1011, and the thermally and electrically conductive layer 110 is filled in the source back hole 1013 and the channel back hole 1015.

The thermally and electrically conductive layer 110 is made of high thermal conductivity metal, such as silver (Ag), copper (Cu), gold (Au), aluminum (Al) or an alloy of the foregoing metal, and preferably, the thermally and electrically conductive layer 110 is made of copper (Cu). It may be understood that the thermally and electrically conductive layer 110 may be made of other thermally and electrically conductive materials, and may be formed on the substrate back surface 1011 in any suitable manner such as electroplating. In addition, the thermally and electrically conductive layer 110 may further be disposed to have a layered structure formed by laminating multiple layers of metal, and the layers may be made of different metal materials as required. For example, metal having good adhesiveness may be first disposed near the substrate 101, such as palladium (Pd), chromium (Cr), and titanium (Ti), where the Pd and the like may further prevent, in a high temperature circumstance, metal from diffusing to a substrate or a semiconductor in contact with the metal, and functions as both an adhesion layer and a diffusion barrier layer; then, metal having lower rigidity is disposed, such as gold (Au), to lower stress imposed by the metal on a material above, and prevent the metal from falling off during process processing; then, a layer formed by using copper is disposed on the foregoing layers and is used as a main electrically and thermally conductive layer; and finally, an oxidation barrier layer such as Au is disposed. In the metal layers, Cu is the thickest.

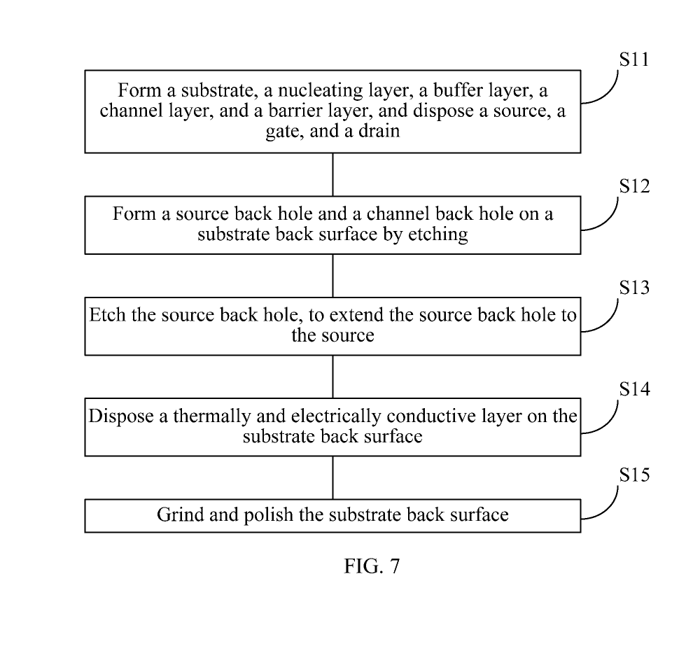

Referring to FIG. 7 together, a HEMT device fabrication method of the HEMT device 100 according to the first exemplary implementation manner of the present invention includes the following steps:

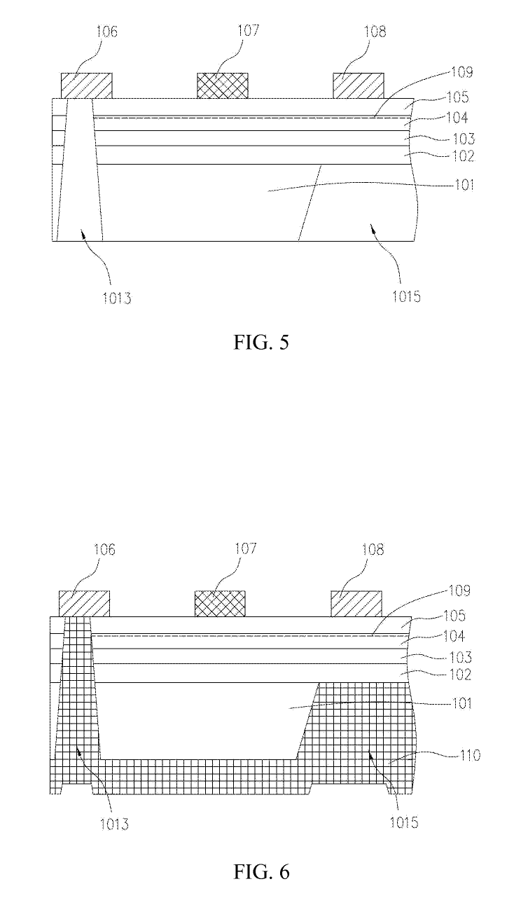

Step S11: Form a substrate 101, a nucleating layer 102, a buffer layer 103, a channel layer 104, and a barrier layer 105 in a laminating manner, and dispose a source 106, a gate 107, and a drain 108 on the barrier layer 105. As shown in FIG. 3, the step specifically includes: forming the nucleating layer 102 on the substrate 101 through deposition; forming the buffer layer 103 on the nucleating layer 102 through deposition; forming the channel layer 104 on the buffer layer 103 through deposition; forming the barrier layer 105 on the channel layer 104 through deposition; forming the source 106 and the drain 108; forming a device separation structure along boundaries of the source 106 and the drain 108; depositing a surface passivation medium layer (not shown in the figure) on the barrier layer 105 so as to suppress current collapse; and forming the gate 107 between the source 106 and the drain 108, where the gate 107 may be a schottky gate in direct contact with the surface of the barrier layer 105, may be a gate 107 in contact with the surface of the passivation medium layer, or may be a gate 107 that is partially in contact with the surface of the barrier layer 105 and partially in contact with the surface of the passivation medium layer and is of a field plate structure. A forming process included in step S11 is consistent with standard processing steps of a HEMT device in the prior art. In the step, other steps may also be added as required, or some steps therein are omitted as required, which are not described herein again.

Step S12: Form a source back hole 1013 and a channel back hole 1015 on a substrate back surface 1011. As shown in FIG. 4, in the step, the source back hole 1013 and the channel back hole 1015 are formed by etching.

Referring to FIG. 1 together, in order to increase output power, the HEMT device 100 generally uses a multi-finger gate structure. A single HEMT device 100 includes multiple sources 106, multiple gates 107, and multiple drains 108, and an etched area includes a conventional source back hole area A and a channel back hole area B that is provided in the present invention. In the HEMT device 100, a channel back hole 1015 covering the entire channel back hole area B may be formed by etching, or several channel back holes 1015 that are disposed at intervals may also be formed by etching, for example, multiple channel back holes 1015 whose length is 100 μm and an interval therebetween is 100 μm may be formed, so as to reduce impacts caused by extra stress of etching and electroplating on device performance. It may be understood that the HEMT device 100 may also be only provided with one source 106, one gate 107, and one drain 108.

In this step, because etching is simultaneously performed in the source back hole area A and the channel back hole area B, an extra photoetching process is not needed, and the etching process is completely consistent with an etching process of a conventional source back hole substrate 101. Because an etching depth is large, an etching mask having a high selection ratio needs to be used, such as Ni (nickel). Conventional steps of the process include: deposition for electroplating seed metal on the substrate 101, performing photoetching to form an etching pattern, electroplating a Ni mask, removing photoresist, etching the seed metal, etching the substrate 101, and finally, etching and removing the Ni mask.

Step S13: Etch the source back hole 1013, to extend the source back hole 1013 to the source 106. As shown in FIG. 5, in this step, the source back hole 1013 is further etched on the nucleating layer 102, the buffer layer 103, the channel layer 104, and the barrier layer 105, and the etching mask directly uses a material of the substrate 101 that is not etched in the previous step. An area of the channel back hole 1015 that does not need to be etched is covered and protected by using photoresist, and the photoresist is removed after the etching is complete.

Step S14: Dispose a thermally and electrically conductive layer 110 on the substrate back surface 1011. The thermally and electrically conductive layer 110 is preferentially made of copper (Cu). Referring to FIG. 6, the thermally and electrically conductive layer 110 is disposed on the substrate back surface 1011 in an electroplating manner, an electroplating thickness of the thermally and electrically conductive layer 110 should be greater than a thickness of each of the source back hole 1013 and the channel back hole 1015, so as to fully fill the source back hole 1013 and the channel back hole 1015, so that impacts of air gaps in the source back hole 1013 and the channel back hole 1015 on heat conduction are removed, and the heat conduction effect is further improved.

Step S15: Referring to FIG. 2 again, in this step, grind and polish the substrate back surface 1011 to make the thermally and electrically conductive layer 110 smooth and glossy.

According to the present invention, a fabrication method compatible with a fabrication process of a conventional AlGaN/GaN HEMT device is used, and the thermally and electrically conductive layer 110 is disposed below the source back hole 1013 and the channel back hole 1015 of the device to replace an original material of the substrate 101, which achieves an effect of improving a heat dissipation capability of the device. It may be understood that, this embodiment may further include steps, such as wafer front side protection, and wafer separation, washing, and scribing, and specific implementation steps thereof are consistent with those of the prior art, which are not described herein again.

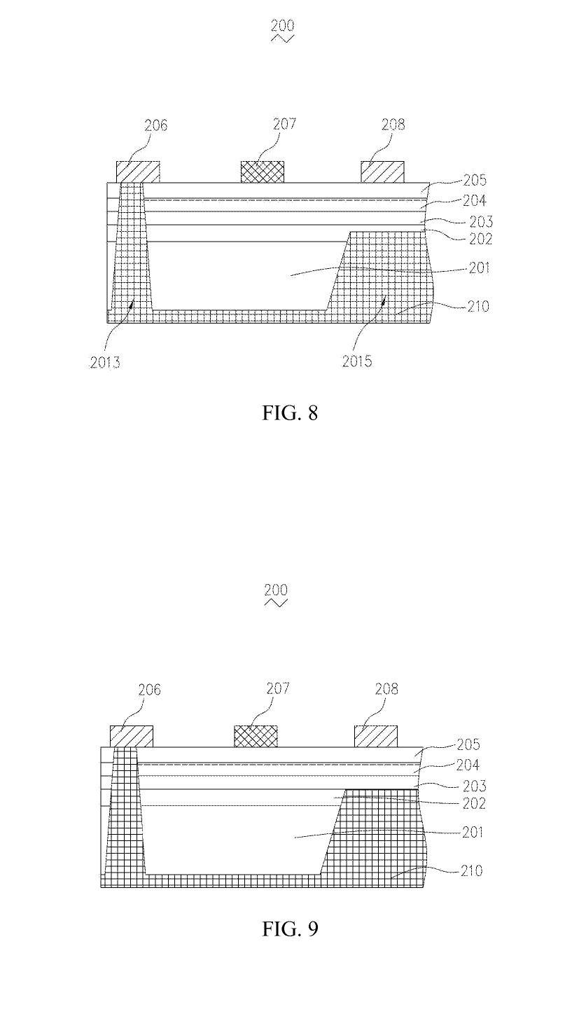

Referring to FIG. 8 to FIG. 11 together, a second exemplary implementation manner of the present invention provides a HEMT device 200, and a structure of the HEMT device 200 is roughly the same as that of the HEMT device 100 in the first exemplary implementation manner. The HEMT device 200 includes a substrate 201, a nucleating layer 202, a buffer layer 203, a channel layer 204, and a barrier layer 205 that are disposed in a laminating manner, and a source 206, a gate 207, and a drain 208 that are formed on the barrier layer 205. The substrate 201 is provided with a substrate back surface 2011, and a source back hole 2013 and a channel back hole 2015 are opened on the substrate back surface 2011. The HEMT device 200 is further provided with a thermally and electrically conductive layer 210, the thermally and electrically conductive layer 210 is formed and covers the substrate back surface 2011, and the thermally and electrically conductive layer 210 is filled in the source back hole 2013 and the channel back hole 2015.

A difference between the HEMT device 200 in this embodiment and the HEMT device 100 in the first exemplary embodiment lies in that:

In this embodiment, the channel back hole 2015 penetrates through the substrate 201, and extends into the HEMT device 200. It may be understood that, as shown in FIG. 8 to FIG. 11, the channel back hole 2015 in this embodiment may further extend into the nucleating layer 202, may further extend to penetrate through the nucleating layer 202, may further penetrate through the nucleating layer 202 and extend into the buffer layer 203, or may further extend and penetrate through the nucleating layer 202 and the buffer layer 203.

Compared with the channel back hole 2015 of the HEMT device 200 in the first exemplary embodiment, the channel back hole 2015 in this embodiment goes deeper into the HEMT device 200, thereby achieving a better heat conduction effect. After the channel back hole 2015 penetrates through the nucleating layer 202 and the buffer layer 203, the thermally and electrically conductive layer 210 may be filled in the channel back hole 2015 and be directly connected to the channel layer 204, so that heat generated by the channel layer 204 is conveniently conducted outwards.

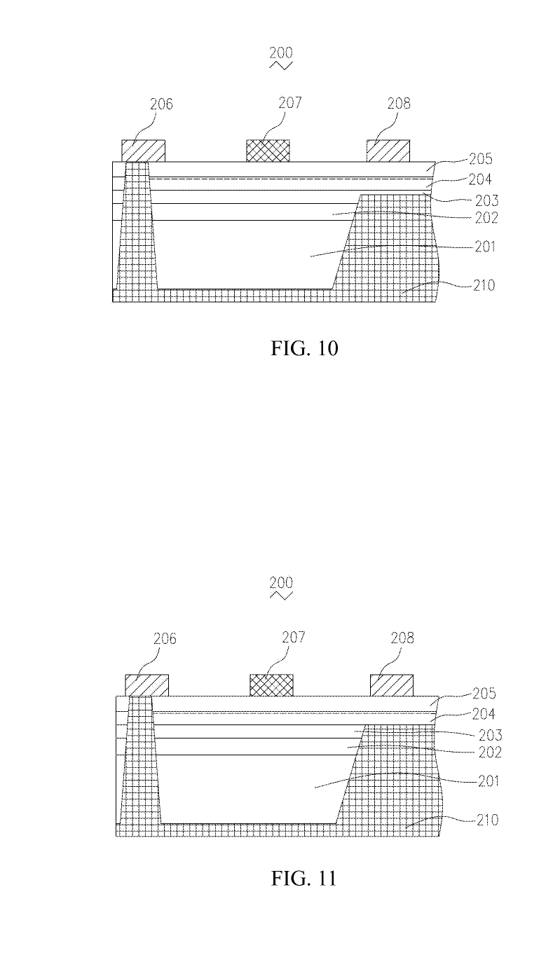

Referring to FIG. 12, a fabrication method of the HEMT device 200 in this embodiment is roughly the same as the fabrication method of the HEMT device 100 in the first exemplary embodiment, and includes the following steps:

Step S11: Form a substrate 201, a nucleating layer 202, a buffer layer 203, a channel layer 204, and a barrier layer 205 in a laminating manner, and form a source 206, a gate 207, and a drain 208 on the barrier layer 205.

Step S12: Form a source back hole 2013 and a channel back hole 2015 on a substrate back surface 2011 by etching.

Step S13: Etch the source back hole 2013, to extend the source back hole 2013 to the source 206.

Step S14: Dispose a thermally and electrically conductive layer 210 on the substrate back surface 2011.

Step S15: Grind and polish the substrate back surface 2011.

A difference between the fabrication method of the HEMT device 200 in this embodiment and the fabrication method of the HEMT device 100 in the first exemplary embodiment lies in that: this embodiment further includes step S12a: Etch a channel back hole 2015, to extend the channel back hole 2015 into the HEMT device. In this step, the nucleating layer 202 and the buffer layer 203 are considered as poor heat conductors, which hinder heat generated in a channel area from being conducted downwards. Therefore, as shown in FIG. 8 to FIG. 11, in step S12a, in a process of further etching the channel back hole 2015, the channel back hole 2015 may extend into the nucleating layer 202 by etching, the channel back hole 2015 may extend by etching so as to penetrate through the nucleating layer 202, the channel back hole 2015 may also extend by etching to penetrate through the nucleating layer 202 and further extend into the buffer layer 203, or the channel back hole 2015 may further extend by etching so as to penetrate through the nucleating layer 202 and the buffer layer 203.

Step S12a is performed after step S12, and a specific implementation manner of step S12a is consistent with that of step S12: After the etching is performed on the substrate 201, a Ni mask is not removed for the moment, instead, the etching is continued to remove the parts of the nucleating layer 202 and the buffer layer 203 at positions corresponding to the channel back hole 2015, and then the Ni mask is removed to perform step S13. It may be understood that, a removal thickness of the buffer layer 203 may be set as required, and it only needs to be ensured that electrical transmission performed by the channel layer 204 is not affected.

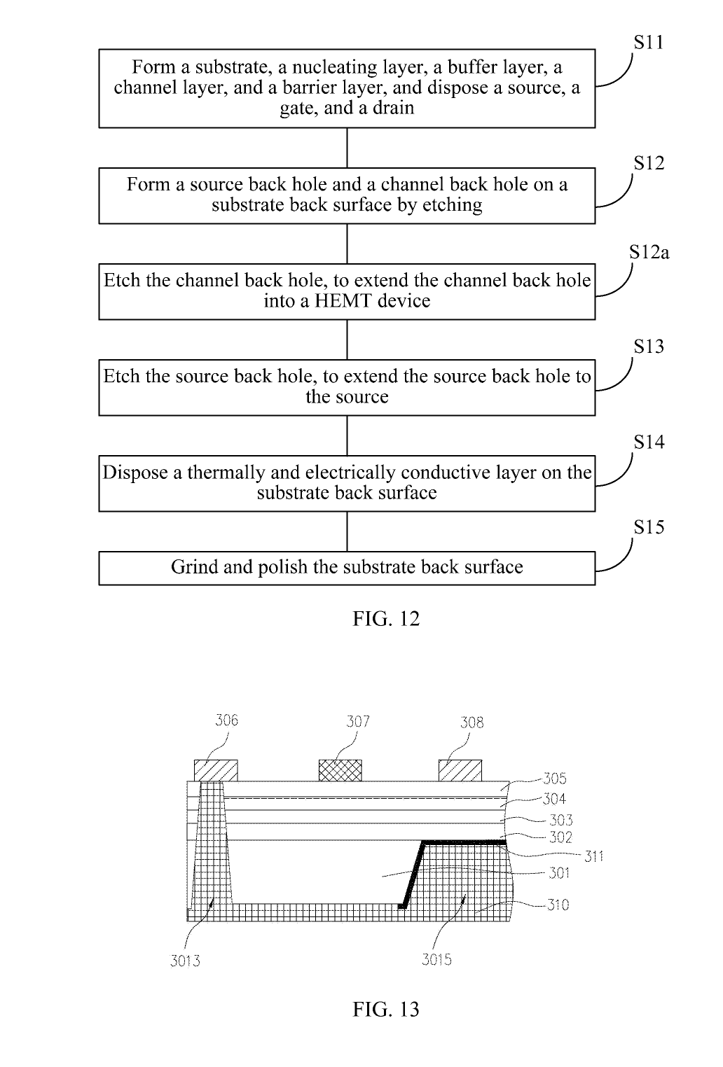

Referring to FIG. 13, a third exemplary implementation manner of the present invention provides a HEMT device 300, and a structure of the HEMT device 300 is roughly the same as those in the first exemplary embodiment and the second exemplary embodiment, and includes a substrate 301, a nucleating layer 302, a buffer layer 303, a channel layer 304, and a barrier layer 305 that are disposed in a laminating manner, and a source 306, a gate 307, and a drain 308 that are formed on the barrier layer 305. The substrate 301 is provided with a substrate back surface 3011, and a source back hole 3013 and a channel back hole 3015 are opened on the substrate back surface 3011. The HEMT device 300 is further provided with a thermally and electrically conductive layer 310, the thermally and electrically conductive layer 310 is formed and covers the substrate back surface 3011, and the thermally and electrically conductive layer 310 is filled in the source back hole 3013 and the channel back hole 3015.

A difference between the HEMT device 300 in this embodiment and the HEMT device 100 in the first exemplary embodiment as well as the HEMT device 200 in the second embodiment lies in that: the HEMT device 300 is further provided with a high heat conducting layer 311, and the high heat conducting layer 311 is disposed on the substrate back surface 3011 of the HEMT device 300 and is disposed between the substrate back surface 3011 and the thermally and electrically conductive layer 310. In this embodiment, the high heat conducting layer 311 is laid in the channel back hole 3015.

In this embodiment, the high heat conducting layer 311 is made of a DLC (Diamond-Like Carbon, diamond-like carbon) material. The DLC material may be obtained by sputtering a graphite target (graphite target) in low temperature or room temperature, and has a good heat conduction capability and price/performance ratio.

In this embodiment, the high heat conducting layer 311 is disposed in the channel back hole 3015, so that heat of the channel layer 304 is conducted and released outwards, and heat dissipation is further performed by using the thermally and electrically conductive layer 310, which improves a heat dissipation capability of the HEMT device 300.

A thermal conductivity coefficient and a thermal diffusion coefficient of a SiC substrate are 370 W/mK and 2 cm²/s respectively; a thermal conductivity coefficient and a thermal diffusion coefficient of the DLC material are: 600 W/mK and 5.2 cm²/s respectively. It can be seen from comparison between the thermal conductivity coefficients and between the thermal diffusion coefficients of the DLC material and the SiC substrate 101 that, besides that a thermal conductivity coefficient of the high heat conducting layer 311 made of the DLC material is greater than that of the substrate made of the SiC material, a thermal diffusion capability of the high heat conducting layer 311 made of the DLC material is also much higher than the that of the substrate 101 made of the SiC material. The thermal diffusion capability is an index for measuring a heat conducting speed of a material. Even though a thickness of the high heat conducting layer 311 made of the DLC material is less than a thickness of the substrate 101 made of the SiC material, the excellent thermal diffusion capability of the high heat conducting layer 311 made of the DLC material still helps conducting heat generated in a channel outwards more quickly, which obviously improves the heat conducting capability of the device. In this embodiment, the thickness of the high heat conducting layer 311 may be set as required.

It may be understood that, a laying position of the high heat conducting layer 311 in the channel back hole 3015 is consistent with an extension depth of the channel back hole 3015, and when the channel back hole 3015 extends into the nucleating layer 302, the high heat conducting layer 311 is laid in the nucleating layer 302 along the channel back hole 3015. In another implementation manner of this embodiment, the high heat conducting layer 311 may slightly extend to the substrate back surface 3011; when the channel back hole 3015 extends and penetrates through the nucleating layer 302 and the buffer layer 303, the high heat conducting layer 311 is in direct contact with and is laid in the channel layer 304, so that heat of the composing layer is better conducted to the thermally and electrically conductive layer 310.

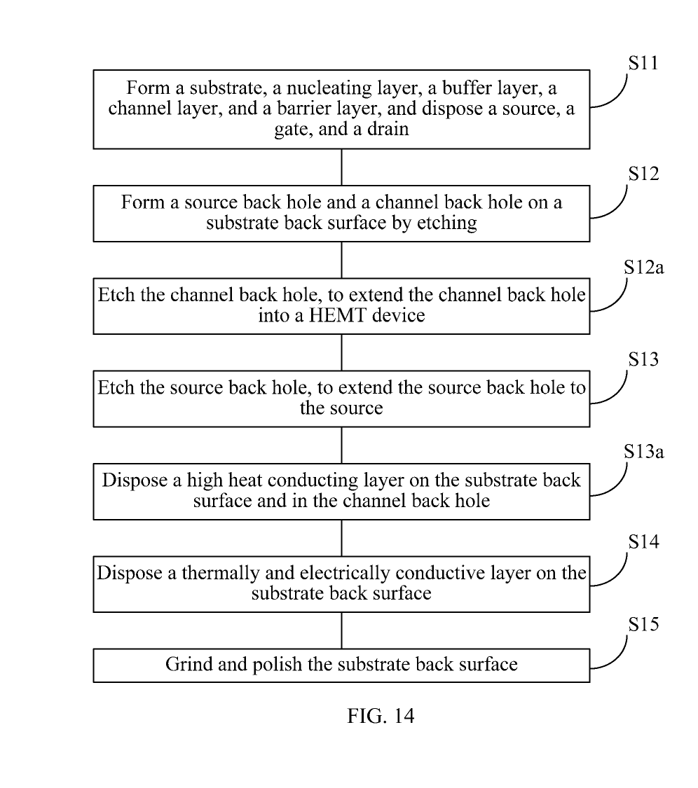

As shown in FIG. 14, a method of the HEMT device 300 in this embodiment is roughly the same as the fabrication method of the HEMT device 100 in the first exemplary implementation manner of the present invention, and includes:

Step S11: Form a substrate 301, a nucleating layer 302, a buffer layer 303, a channel layer 304, and a barrier layer 305 in a laminating manner, and form a source 306, a gate 307, and a drain 308 on the barrier layer 305.

Step S12: Form a source back hole 3013 and a channel back hole 3015 on a substrate back surface 3011 by etching.

Step S13: Etch the source back hole 3013, to extend the source back hole 3013 to the source 306.

Step S14: Dispose a thermally and electrically conductive layer 310 on the substrate back surface 3011.

Step S15: Grind and polish the substrate back surface 3011.

A difference between the fabrication method of the HEMT device 300 in this embodiment and the fabrication method of the HEMT device 100 in the first exemplary embodiment lies in that: the fabrication method of the HEMT device 300 in this embodiment further includes step 13a: Dispose a high heat conducting layer 311 on the substrate back surface 3011 and in the channel back hole 3015. Step 13a is performed before step S14.

In this step, the high heat conducting layer 311 is made of a DLC material, and is disposed on the substrate back surface 3011 and in the channel back hole 3015 in a deposition manner. The deposition manner is low-temperature or room-temperature deposition, and includes ion beam (ion beam) deposition, sputtering (sputtering), and the like. A thickness of deposition is as large as possible on the premise that the process can be performed, and generally should be greater than 2 μm.

The present invention provides a HEMT device having a high heat dissipation capability and a fabrication method of the HEMT device. According to the HEMT device manufactured by using the HEMT fabrication method in the present invention, a channel back hole is formed, a high heat conducting layer is formed in the channel back hole through deposition, and a thermally and electrically conductive layer is electroplated on a substrate back surface, so that a heat conducting capability is improved, and a source is connected to a metal ground of the substrate back surface through a source back hole. The high heat conducting layer 311 and the thermally and electrically conductive layer of the HEMT device of the present invention are formed through low-temperature or room-temperature deposition after the source back hole and the channel back hole are etched. The fabrication method is compatible with a process of a conventional source back hole, which does not affect performance of the HEMT device.

The foregoing descriptions are merely exemplary embodiments of the present invention, and are not intended to limit the scope of the present invention. A person of ordinary skill in the art may understand all or some processes of the foregoing embodiments, and equivalent modifications made according to the claims of the present invention shall still fall within the scope of the present invention.

1. A HEMT (high electron mobility transistor) device, comprising:
a substrate, a nucleating layer, a buffer layer, a channel layer, and a barrier layer that are disposed in a laminating manner;
a source, a gate, and a drain that are formed on the barrier layer;
a thermally and electrically conductive layer,
wherein:
the drain is disposed between the source and the gate,
the substrate is provided with a device surface disposed facing the nucleating layer and a substrate back surface away from the device surface,
a source back hole and a channel back hole are opened on the substrate back surface,
the source back hole penetrates through the substrate, the nucleating layer, the buffer layer, the channel layer, and the barrier layer and extends to the source,
the channel back hole penetrates through at least one part of the substrate, and
the thermally and electrically conductive layer is filled in the source back hole and the channel back hole and covers the substrate back surface.

2. The HEMT device according to claim 1, wherein the thermally and electrically conductive layer is made of high thermal conductivity metal.

3. The HEMT device according to claim 2, wherein the thermally and electrically conductive layer is made of copper.

4. The HEMT device according to claim 1, wherein the channel back hole penetrates through the substrate.

5. The HEMT device according to claim 1, wherein the channel back hole penetrates through the substrate, and the channel back hole extends into the nucleating layer.

6. The HEMT device according to claim 1, wherein the channel back hole penetrates through the substrate and the nucleating layer.

7. The HEMT device according to claim 1, wherein the channel back hole penetrates through the substrate and the nucleating layer, and the channel back hole extends into the buffer layer.

8. The HEMT device according to claim 1, wherein the channel back hole penetrates through the substrate, the nucleating layer, and the buffer layer.

9. The HEMT device according to claim 4, further comprising:
a high heat conducting layer, wherein the high heat conducting layer is laid in the channel back hole, and the high heat conducting layer is disposed between the substrate back surface and the thermally and electrically conductive layer.

10. The HEMT device according to claim 9, wherein the high heat conducting layer is made of a diamond-like carbon material.

11. A HEMT (high electron mobility transistor) device fabrication method, comprising:
disposing a substrate, a nucleating layer, a buffer layer, a channel layer, and a barrier layer;
disposing a source, a gate, and a drain on the barrier layer, so that the drain is disposed between the source and the gate;
forming a source back hole and a channel back hole on a substrate back surface, wherein the channel back hole penetrates through at least one part of the substrate;
making the source back hole penetrate through the substrate, the nucleating layer, the buffer layer, the channel layer, and the barrier layer and extend to the source; and
disposing a thermally and electrically conductive layer on the substrate back surface, wherein the thermally and electrically conductive layer is filled in the source back hole and the channel back hole and covers the substrate back surface.

12. The HEMT device fabrication method according to claim 11, wherein the forming the source back hole and the channel back hole on the substrate back surface comprises:
forming the source back hole and the channel back hole by etching.

13. The HEMT device fabrication method according to claim 11, wherein after the forming the source back hole and the channel back hole on the substrate back surface, the HEMT device fabrication method further comprises:
etching the channel back hole to extend the channel back hole into the HEMT device.

14. The HEMT device fabrication method according to claim 13, wherein the etching the channel back hole comprises:
extending the channel back hole into the nucleating layer.

15. The HEMT device fabrication method according to claim 13, wherein the etching the channel back hole comprises:
etching the channel back hole so as to penetrate through the nucleating layer.

16. The HEMT device fabrication method according to claim 13, wherein the etching the channel back hole comprises:
etching the channel back hole, to extend the channel back hole into the buffer layer.

17. The HEMT device fabrication method according to claim 13, wherein the etching the channel back hole comprises:
etching the channel back hole so as to penetrate through the nucleating layer and the buffer layer.

18. The HEMT device fabrication method according to claim 11, wherein before the disposing the thermally and electrically conductive layer on the substrate back surface, the HEMT device fabrication method further comprises:
disposing a high heat conducting layer in the channel back hole.

19. The HEMT device fabrication method according to claim 11, wherein after the disposing the thermally and electrically conductive layer on the substrate back surface, the HEMT device fabrication method further comprises:
grinding and polishing the substrate back surface.

20. The HEMT device fabrication method according to claim 19, wherein when the thermally and electrically conductive layer is disposed on the substrate back surface, a thickness of the thermally and electrically conductive layer is greater than a depth of each of the source back hole and the channel back hole.
